(19) United States
(12) Patent Application Publication
(10) Pub. No.: US 2025/0338521 A1
(43) Pub. Date: Oct. 30, 2025

(54) THIN FILM RESISTOR INTEGRATION WITH TERMINALS

(71) Applicant: TEXAS INSTRUMENTS INCORPORATED, Dallas, TX (US)

(72) Inventors: Hongmei Li, Allen, TX (US); Qi-Zhong Hong, Richardson, TX (US); Shan-Chung Pan, Allen, TX (US)

(21) Appl. No.: 18/648,965

(22) Filed: Apr. 29, 2024

(51) Int. Cl. H10D 1/47

(52) U.S. Cl. CPC H10D 1/474

(57) ABSTRACT

An integrated circuit (IC) including a TFR is disclosed. In one example, the IC comprises a first dielectric layer over a semiconductor substrate, first and second metal terminals extending from a top surface of the first dielectric layer toward the semiconductor substrate, a resistive layer extending between and electrically connected to the first and second metal terminals, and a second dielectric layer over and in direct contact with the resistive layer.

### FIELD OF THE DISCLOSURE

Disclosed implementations relate generally to the field of integrated circuits (ICs) and IC fabrication. More particularly, but not exclusively, the disclosed implementations relate to thin film resistor (TFR) integration.

### BACKGROUND

Metal thin film resistors (TFRs) may be formed using a variety of resistive metals. Nichrome (NiCr) and sichrome (SiCr) are two that are commonly used. These types of TFRs are formed in the backend of line (BEOL) of an integrated circuit manufacturing flow. BEOL resistors have less parasitic capacitance than resistors formed in the frontend of line (FEOL) that typically use polysilicon, silicide, or nwell formed in or over the semiconductor substrate because BEOL resistors are formed at a greater distance from the semiconductor substrate.

Integrating a metal TFR in the BEOL of an integrated circuit manufacturing flow adds cost and cycle time. As the advances in the design of interconnects formed in BEOL continue to take place, improvements in microelectronic devices, including metal TFRs and their integration, are also being concomitantly pursued.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

Examples of the present disclosure are directed to an IC (also referred to as an electronic device, IC device, semiconductor device, etc.) including one or more TFRs integrated with metal terminals formed in a BEOL or a pre-BEOL stage. In one example, an IC is disclosed, which may comprise, among others, a first dielectric layer over a semiconductor substrate; first and second metal terminals extending from a top surface of the first dielectric layer toward the semiconductor substrate; a resistive layer extending between and electrically connected to the first and second metal terminals; and a second dielectric layer over and in direct contact with the resistive layer.

In one example, a method of fabricating an IC device including a TFR is disclosed. The method may comprise, among others, forming a first dielectric layer over a semiconductor substrate; forming first and second metal terminals extending from a top surface of the first dielectric layer toward the semiconductor substrate; forming a resistive layer extending between and electrically connected to the first and second metal terminals; and forming a second dielectric layer over and in direct contact with the resistive layer.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure described in the following Detailed Description taken in connection with the appended claims and with reference to the attached drawing Figures in which:

FIGS. 1A to 1L-3 illustrate sectional views of a semiconductor device at progressive stages of fabrication where a thin film resistor may be integrated according to some examples of the present disclosure; and

FIG. 2 is a flowchart relating to a fabrication method according to some examples of the present disclosure.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of the present disclosure will be set forth below in the context of thin film resistor (TFR) integration in the manufacture of semiconductor device fabrication where conductive terminals associated with a TFR may be formed in an interconnect stage in a BEOL flow and/or a pre-metallization stage before the BEOL flow.

Thin film resistors (TFRs) may offer low temperature coefficient of resistance (TCR) and have many applications. For example, high precision analog circuits (e.g., voltage references, digital-to-analog and analog-to-digital converters (DACs/ADCs), biosensing analog frontends (AFEs), etc.) may include one or more TFRs because of the low TCR. In some baseline processes, a TFR may be formed between a metallization layer and an adjacent metallization layer formed in the BEOL processing of a semiconductor device. Such inter-level metal integration of TFRs requires the formation of TFR head structures where vias can land and make contact with the TFR film. In some examples, the TFR head structures may need a minimum thickness of a dielectric layer (e.g., 400 nanometers (nm) or more). As interconnect technologies continue to advance, the inter-level dielectric (ILD) layers are becoming thinner, thus potentially limiting the ability to integrate TFRs between metal layers.

Examples of the present disclosure recognize these and other shortcomings and advantageously provide TFR arrangements where a resistive body of a TFR may be electrically coupled to or otherwise integrated with conductive terminals formed in a metallization layer (e.g., in a top level layer). Some additional and/or alternative examples provide TFR arrangements where a TFR may be electrically coupled to or otherwise integrated with conductive terminals formed in a pre-metallization stage, which may allow high-temperature annealing (HTA) required for increasing film resistivity in certain applications without compromising the integrity of metal interconnects that may be formed subsequently. Additionally, example TFR structures may be provided with reduced thickness relative to baseline TFR structures because of the integration scheme set forth herein. While such examples provide materials and processes that advantageously allow TFR integration in a variety of interconnect schemes involving different metals, e.g., copper, aluminum, etc., no particular result is a requirement unless explicitly recited in a particular claim.

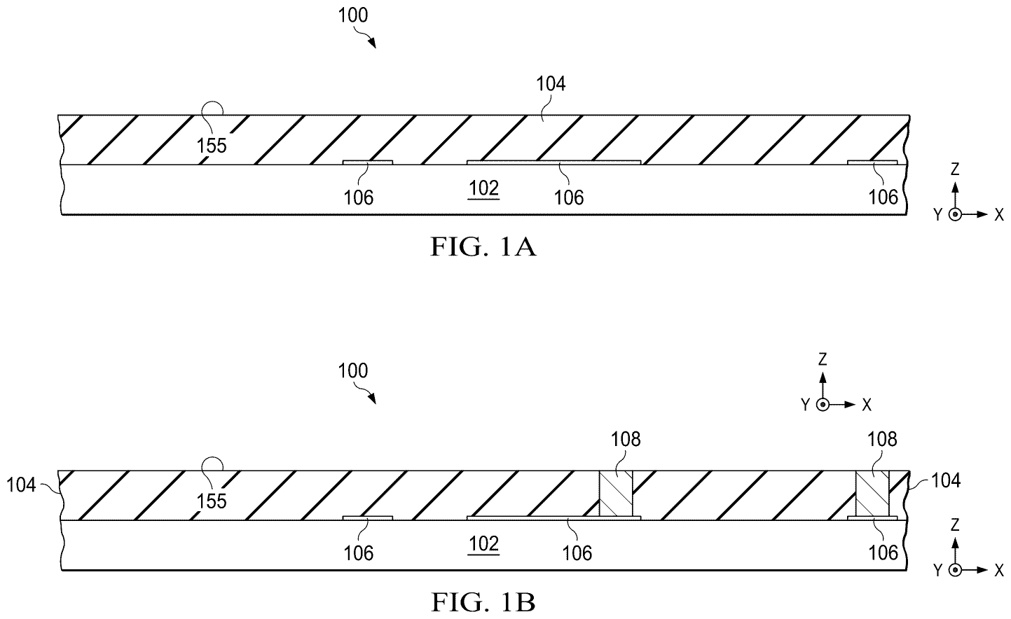

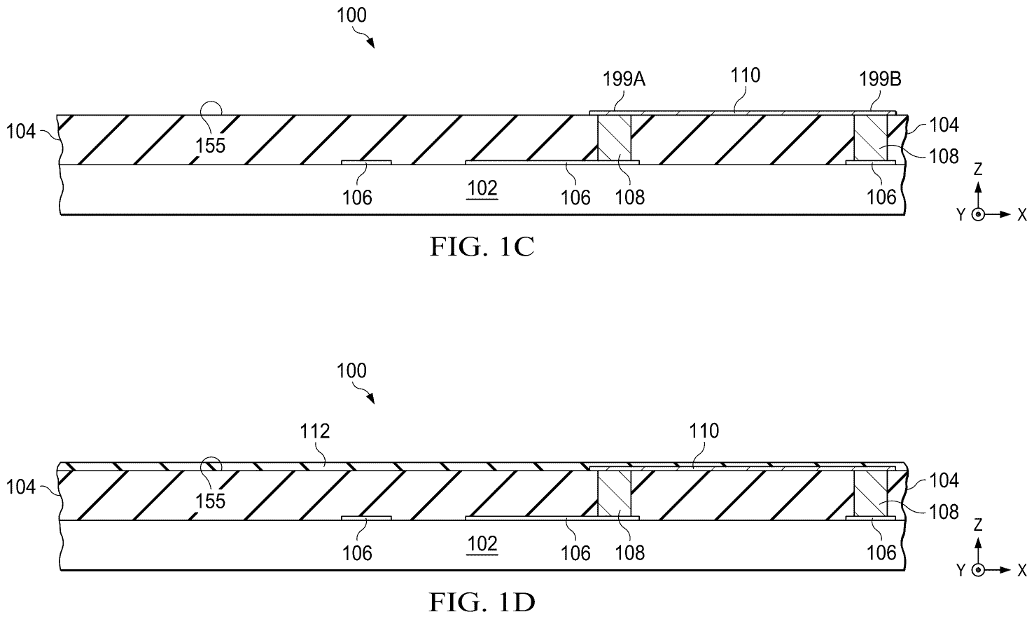

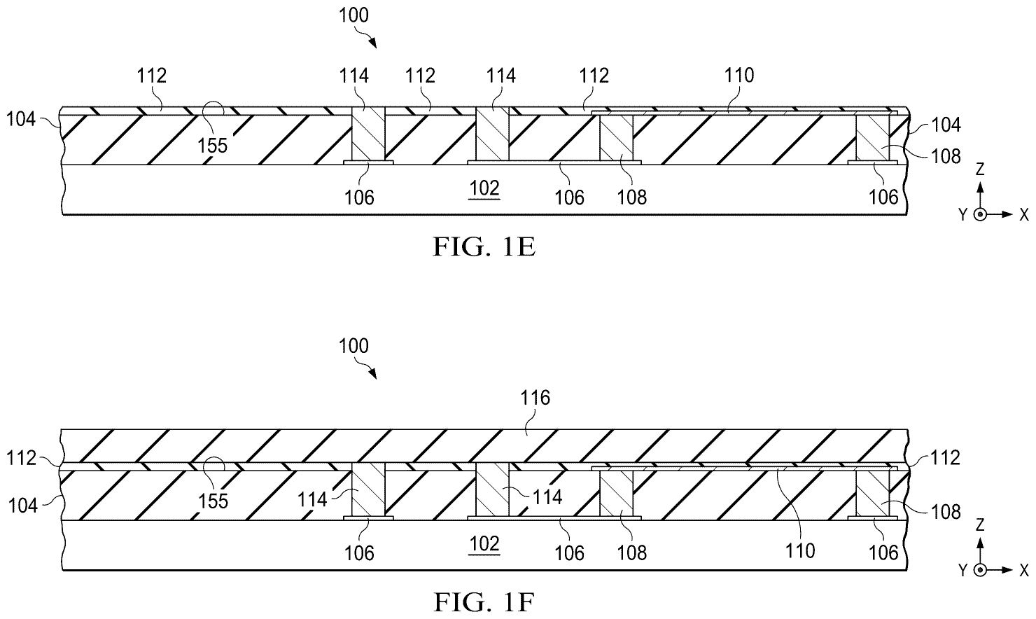

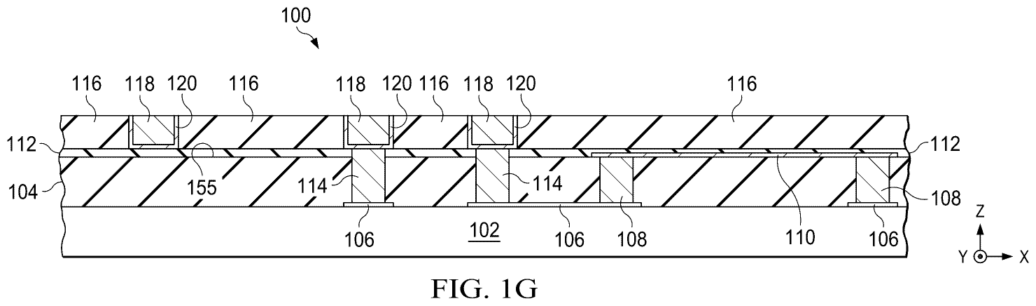

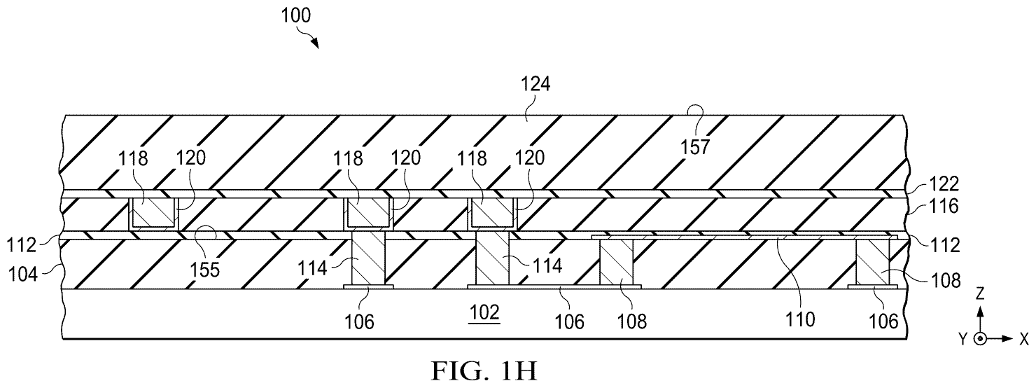

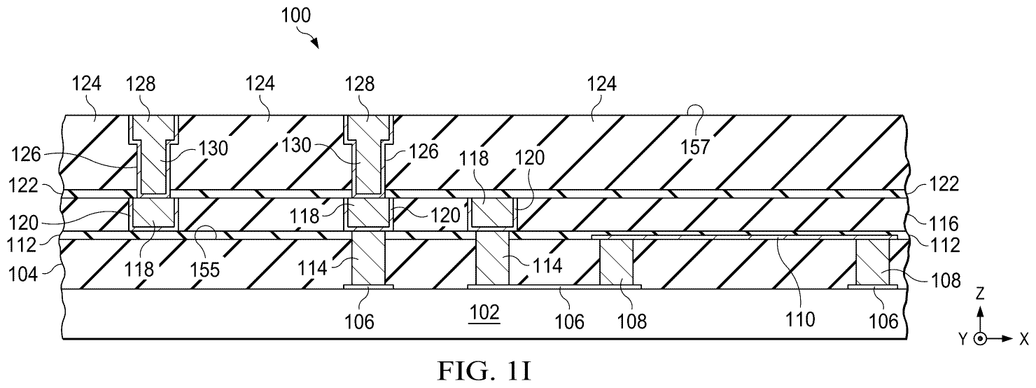

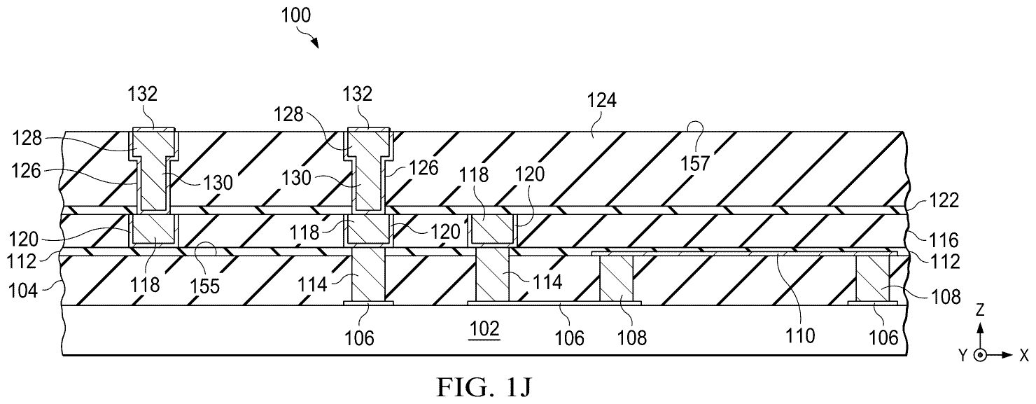

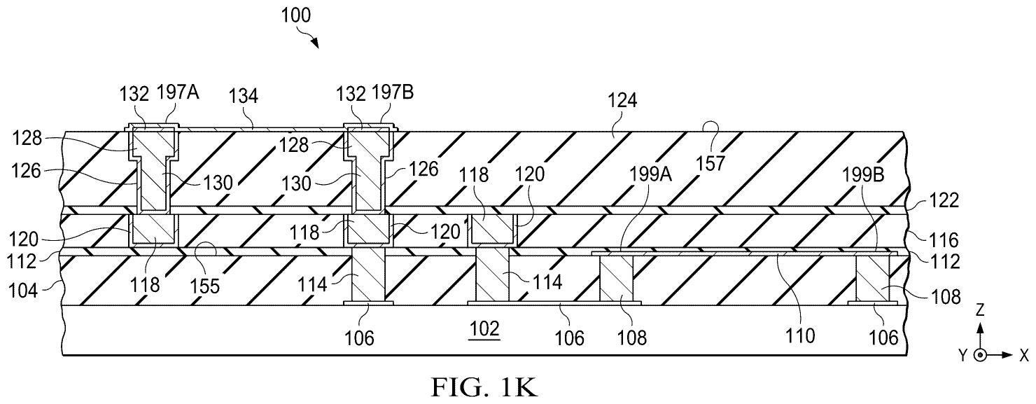

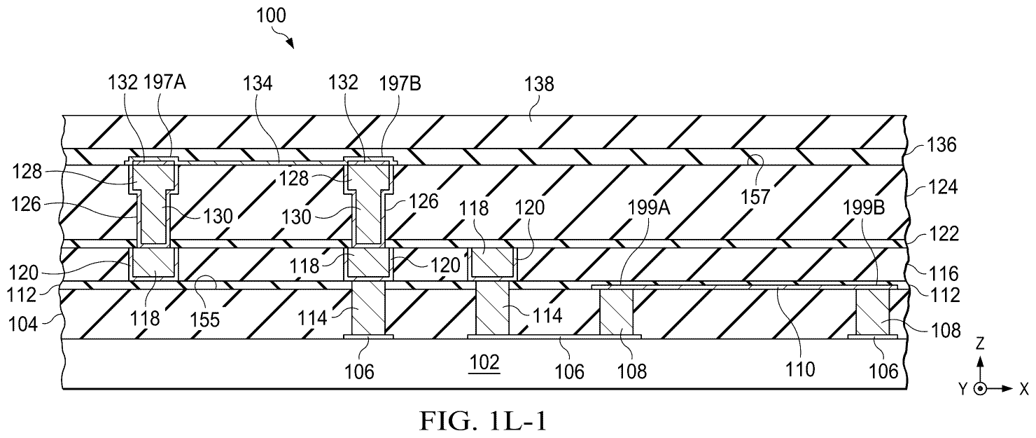

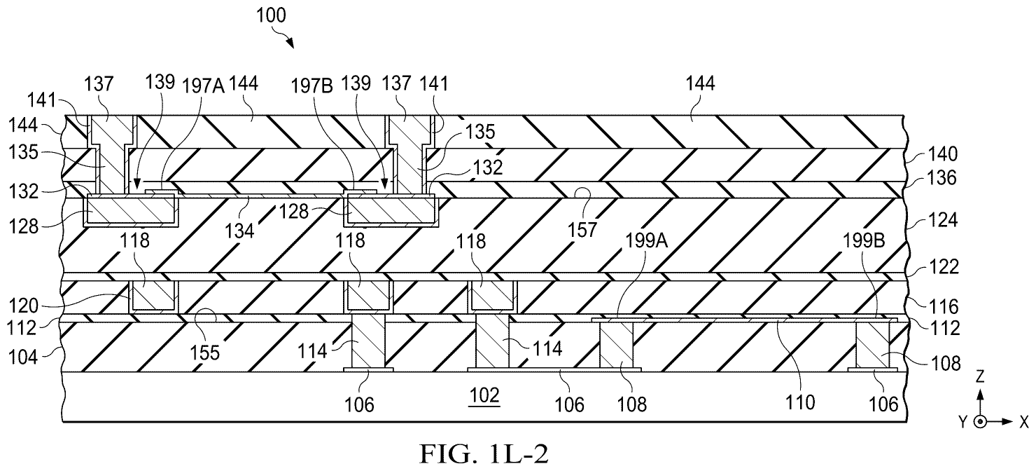

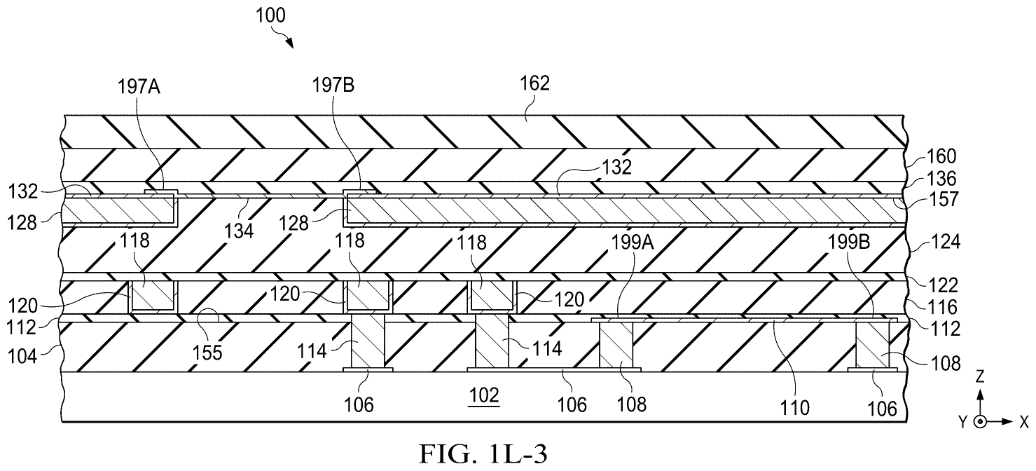

FIG. 1A to FIGS. 1L-1/1L-2/1L-3 illustrate sectional views of a semiconductor device 100, e.g., an IC device or a discrete device, at progressive stages of fabrication where one or more TFRs may be integrated in different flows according to some examples of the present disclosure. In one arrangement, a subset of the illustrated process stages may be implemented in an example flow to obtain a TFR arrangement where a resistive film or layer operable as a TFR may be integrated within a multilevel interconnect arrangement of the semiconductor device 100. In such an arrangement, metal interconnect structures of a horizontal routing layer of the multilevel interconnect arrangement may be configured as conductive terminals operable to establish electrical contact with respective termini of TFR. Depending on application, the conductive terminals may be appropriately routed for facilitating access to the TFR, for example, using an upper level metal interconnect layer, a lower level metal interconnect layer, or a same level metal interconnect layer, and/or a combination thereof. In another arrangement, a subset of the illustrated process stages may be implemented in an example flow, which may share some process stages with other process flows, to obtain a TFR arrangement where a resistive film or layer operable as a TFR may be integrated in a pre-metallization stage of fabrication (e.g., before BEOL but after completing the fabrication of circuit elements such as transistors, diodes, etc., in a frontend of line (FEOL) flow). In such arrangements, conductive terminals formed in the pre-metallization stage of the semiconductor device 100 may be configured to provide access to and/or establish electrical contact with the TFR, where a polysilicon interconnect may be used for routing. In yet another arrangement, a subset of the illustrated process stages may be implemented in an example flow to obtain a TFR arrangement where multiple TFRs integrated at different stages may be provided as part of the semiconductor device 100.

For the sake of clarity, the illustrated sectional views do not show the details of microelectronic devices and components, e.g., transistors, isolation regions, laterally diffused extensions, N-wells, P-wells, deep wells, shallow wells, etc., already formed in or over a semiconductor substrate 102 of the semiconductor device 100 as part of a FEOL fabrication flow. In representative examples, the transistors may include nMOS or pMOS transistors, junction field effect transistors (JFETs), NPN or PNP bipolar transistors, biCMOS transistors, Group III-Nitride devices, or combinations thereof. Depending on implementation, the semiconductor device 100 may be representative of a device including analog, digital and/or mixed signal circuitry that may be fabricated using any type or combination of fabrication technologies and/or technology nodes. For example, the semiconductor device 100 may be a device where different technologies suitable for respective types of product design may be integrated within the same chip or IC device, e.g., linear BiCMOS or LBC (a bipolar-CMOS combination technology where MOS and bipolar technology may be used for analog functions and CMOS may be used for digital logic design), BCD (a bipolar-CMOS-DMOS combination technology where DMOS may be integrated within the IC device for power and high-voltage portions that also has analog and digital portions), and the like. In some examples, the semiconductor device 100 may be representative of an ADC/DAC converter, where a TFR may be provided as part of a resistive ladder network, without limitation.

FIG. 1A depicts a cross-sectional view of the semiconductor device 100 at a pre-metallization stage, e.g., after forming various circuit elements over or in the semiconductor substrate 102 in a FEOL flow. The semiconductor substrate 102 may predominantly comprise suitably doped silicon as substate material in some examples, although other semiconductor materials such as silicon-on-insulator, Ge, SiGe, GaAs, SiC, GaN, other Group III-V materials, etc., may be used in some implementations, where one or more epitaxial layers or single-crystal layers may be formed or provided as part of the semiconductor substrate 102. Further, the cross-sectional view of FIG. 1A also depicts the formation of various polysilicon interconnects or traces 106 formed between the semiconductor substrate 102 and a pre-metal dielectric (PMD) layer 104 formed over the semiconductor substrate 102. In some arrangements, the PMD layer 104 may comprise doped dielectric material, e.g., phosphorous-doped silicate glass (PSG). Depending on implementation, polysilicon interconnects 106 may have a suitable thickness and may be silicided appropriately (not specifically shown in the Figures) where metallic contacts are to be formed through the PMD layer 104. An example silicidation loop for use with the polysilicon interconnects 106 may comprise deposition of a metal (e.g., nickel (Ni), cobalt (Co), titanium (Ti), tungsten (W), molybdenum (Mo), platinum (Pt), palladium (Pd), tantalum (Ta), etc., without limitation), annealing to form silicide (e.g., using heat, ionic energy, laser energy, etc.), followed by the removal of unreacted metal and further annealing to a form low resistivity phase of the silicide material. Although not specifically shown in the Figures, the PMD layer 104 may include one or more layers formed of different materials, e.g., silicon nitride (SiN) or silicon dioxide (SiO₂), etc., that may be planarized (e.g., by chemical mechanical polishing (CMP) and/or etchback) to a total thickness of about 0.3 microns (μm) to 2 μm or more. In some examples, the PMD layer 104 may be formed by plasma enhanced chemical vapor deposition (PECVD) and/or by a high density plasma (HDP) deposition.

FIG. 1B depicts a stage of the semiconductor device 100 where metallic contacts are formed in the PMD layer 104 using a contact pattern and etch process, where the contacts may be configured to land on silicided polysilicon interconnects 106. Depending on implementation with respect to pre-BEOL metallization, contact formation in the PMD layer 104 may include one or more process loops where different contacts may be formed based on the required connectivity. Further, the contacts may have different form factors, e.g., having circular, square or rectangular cross-sections with variable heights. In some examples, a set of contacts may be formed for providing connectivity with respect to one or more metal layers of an interconnect system to be formed over the PMD layer 104. In some examples, a set of contacts may be formed for providing connectivity with respect to TFRs that may be integrated with metal terminals formed in corresponding metal layers of the multilevel interconnect system. In some examples, a set of contacts may be formed, e.g., contacts 108, for providing connectivity with respect to a pre-BEOL TFR that may be electrically coupled to the contacts 108 operable as first and second metal terminals for the TFR.

Without limitation, some examples of contact formation are set forth herein. In some implementations, contacts may include an adhesion liner of titanium formed by a sputter process. In some implementations, contacts may include a barrier liner of titanium nitride (TiN) or tantalum nitride (TaN) on the adhesion liner, e.g., where copper is used for contact formation. Example barrier liners may be formed by a reactive sputter process, an atomic layer deposition (ALD) process, etc., and may include a variety of metallic/oxide/nitride compositions. In some implementations, contacts may include a fill plug of tungsten on the barrier liner, formed by a metal organic chemical vapor deposition (MOCVD) process including reduction of tungsten hexafluoride. In some implementations, any overburden of the fill plug metal, barrier liner and adhesion liner on a top surface 155 of the PMD layer 104 may be removed by a CMP process, an etchback process, or a combination of both.

In the representative example of FIG. 1B, the contacts 108 may comprise tungsten plugs having a thickness (e.g., width, diameter or a similar horizontal dimension along the X-axis) around 0.02 μm to 0.4 μm and a height of about 0.3 μm to 2 μm depending on implementation and consistent with the PMD layer 104. As will be seen further below, the contacts 108 may be configured to operate as terminals extending from the top surface 155 of the PMD layer 104 toward the semiconductor substrate 102 for providing connectivity with respect to a TFR structure.

FIG. 1C depicts a stage where a resistive layer 110 is formed over the PMD layer 104 having an electrically conductive relationship with the contacts 108. A thin film deposition, pattern and etch process may be used for forming a resistive layer 110 that may be patterned to have a first terminus 199A and a second terminus 199B over the contacts 108, respectively, which may also be referred to as first and second metal terminals in some arrangements. In some examples of the present disclosure, the resistive layer 110 is operable as a pre-BEOL TFR where polysilicon routing is used for providing access and connectivity. The resistive layer 110 may have a suitable thickness (e.g., around 3 nm to 50 nm or less) and sufficient resistivity (e.g., greater than 100 u (2-cm), and may comprise a variety of compositions suitable for TFR formation including at least one transitional metal element. In some implementations, the resistive layer 110, also referred to as a TFR layer or a resistive body in some examples, may include a silicon chromium (SiCr) based mixture with an example composition (in relative atomic %) of SiₓCr_{y}C_{z}O_{w}, where x and y can range from 5% to 50%, whereas z and w can range from 0% to 50%. In another implementation, for example, the resistive layer 110 may include a nickel chromium (NiCr) based mixture with an example composition (in relative atomic %) of NiₓCr_{y}C_{z}O_{w}, where x and y can range from 5% to 50%, whereas z and w can range from 0% to 50%. In some examples, desirable resistive materials for forming the resistive layer 110 may include SiCr, NiCr, TaN, SiCCr (silicon carbide-chromium), AlNiCr (aluminum-nickel-chromium), or TiNiCr (titanium-nickel-chromium), without limitation. In general, such resistive materials may be desirable as they have a low TCR (e.g., equal to or less than about 30 ppm/° C.) and because the resistive bodies comprising such materials are capable of having their resistance tuned by various baseline laser trimming processes.

The resistive layer 110 may be formed in various ways depending on the materials used for forming a resistive body of the TFR. Without limitation, physical vapor deposition (PVD) processes such as evaporation or sputtering may be used to deposit the resistive layer 110 in some examples. Depositing the resistive layer 110 may include annealing the layer 110 (e.g., about 410° C. in air for about 30 minutes followed by about 410° C. in a forming gas (e.g., 20% H₂ and a balance of N₂) for about 30 minutes) in some implementations.

Depending on whether a damascene interconnect fabrication flow (e.g., using copper) or a non-damascene interconnect fabrication flow (e.g., using aluminum) is implemented in subsequent BEOL stages, a hardmask layer may be optionally used in the TFR formation in some configurations. In examples where a copper interconnect is implemented, the use of a hardmask is optional because the inlay formation of copper layers in a damascene process does not compromise the TFR. In contrast, where an aluminum interconnect is implemented, a TFR hardmask layer may be provided in order to protect the resistive layer 110 during the non-damascene metal deposition and etch process. In the representative example of FIG. 1C, a TFR hardmask is not specifically shown. Where a TFR hardmask layer is implemented, low deposition rate (LDR) tetra-ethyl-ortho-silicate (TEOS) and silane may be used as source gases to form a SiO₂ hardmask layer of about 20 nm to 60 nm over the resistive layer 110 in an LPCVD process. In other examples, the hardmask layer may comprise silicon nitride (SiN), silicon oxynitride (SiON), silicon carbide (SiC) or combinations thereof. The resistive layer 110 (and the hardmask layer where implemented) may be patterned using any suitable etch (e.g., a dry etch process such as reactive ion etching or RIE).

Where a copper interconnect is implemented, an etch stop layer 112 may be formed over the resistive layer 110 as depicted in FIG. 1D. In some examples, the etch stop layer 112 may also function as a dielectric diffusion barrier layer. Further, the etch stop layer 112 may be referred to as a second dielectric layer in reference to the PMD layer 104, which may be referred to as a first dielectric layer for purposes of some examples. As used herein, the terminology of “first dielectric layer”, “second dielectric layer”, etc., may respectively refer to different dielectric layers of a semiconductor device that are formed after a FEOL flow depending on the type of TFR integration implemented, and are not necessarily limited to the PMD layer 104 and the etch stop layer 112 shown in FIG. 1D. For example, the first and second dielectric layers may also refer to various levels of inter-level dielectrics (ILDs) and/or inter- or intra-metal dielectrics (IMDs) formed in a BEOL flow depending on the levels of metal layers used in an interconnect arrangement as will be seen further below.

In some examples, the etch stop layer 112 may have a thickness of about 30 nm to 80 nm and may comprise SiCN, SiC, SiCO, SiON, or Si₃N₄, and the like. In some examples where an aluminum interconnect scheme is implemented, an etch stop layer may not be necessary because of the non-damascene fabrication process.

In some examples, a high-temperature annealing (HTA) process may be implemented in order to increase the resistivity of a pre-BEOL TFR such as the resistive layer 110. Depending on implementation, annealing temperatures of about 300° C. to 650° C. may be applied over shorter or longer periods of time (e.g., about 30 minutes) to increase the resistivity by or up to three times or more. Higher resistivity is generally desired in a design layout as the size of a TFR may be reduced for given electrical performance requirements, thus saving the chip area of a semiconductor device such as the device 100. Because pre-BEOL TFR integration as set forth herein may be completed before the formation of metal interconnect layers in a BEOL flow, an example flow that concludes the TFR integration at this stage may be particularly advantageous over a TFR integration scheme where the TFR is formed in the BEOL flow, as the HTA process may compromise the metal interconnects already formed prior to the formation of the TFR.

FIG. 1E depicts an optional stage where contacts 114 are formed in the PMD layer 104 and through the etch stop layer 112 for providing connectivity with respect to one or more metal interconnect layers and/or additional TFRs that may be integrated in association with one or more interconnect layers of a BEOL flow. Depending on implementation and the interconnect metallurgy used, the contacts 114 may comprise plugs formed of tungsten, copper, etc., and may have suitable form factors as described above. In some arrangements, the contacts 114 may be formed together with the contacts 108 as set forth above, which can reduce the number of mask steps in a flow.

FIG. 1F depicts a stage where an inter-metal dielectric (IMD) 116 having a thickness of about 80 nm to 500 nm is formed over the etch stop layer 112 and contacts 114 where provided. In some examples, the IMD 116 may comprise one or more sublayers and may include SiO₂, undoped or doped silicate glass, spin-on-glass, fluorosilicate glass or other low-k dielectric constant material (e.g., a dielectric constant of less than about 4), which may be deposited using suitable baseline procedures. In some examples, the IMD 116 may be planarized, e.g., with CMP and/or etchback. In some examples involving aluminum interconnect, the IMD 116 may be operable as a second dielectric layer with respect to the PMD layer 104.

FIG. 1G depicts a stage where one or more metal interconnect structures 118 are formed in the IMD 116. Depending on implementation, the metal interconnect structures 118 may be formed as part of fabricating a first metal layer, e.g., comprising copper, that may be provided as a first metallization level of a multilevel interconnect arrangement of the semiconductor device 100. In some examples, the first metal layer may be labeled MET1, MT1, or M1, or with terms of similar import. In an example copper interconnect arrangement, a barrier layer 120 having a thickness of about 2 nm may be formed surrounding the copper interconnect structures 118 to enhance the ohmic contact and adhesion of the interconnect structures 118 as well as function as a barrier against copper diffusion or migration into the surrounding dielectric materials at high temperatures that may be encountered during subsequent processing. Example diffusion/migration barrier materials may comprise transition metals such as Ta, W and Ti as well as their compositions with nitrogen (N), carbon (C), and/or silicon (Si), resulting in refractory compounds including Ta/TaN, W₂N, TIN, TIC, TaSiN, Si₃N₄, and the like. Additional and/or alternative examples herein may include barrier materials comprising platinum group metals (PGMs) such as ruthenium (Ru)-based materials, self-assembled molecular layers (SAMs) and high-entropy alloys (HEAs).

FIG. 1H depicts a stage where one or more layers/sublayers of a next level dielectric layer stack are formed over the metal interconnect structures 118. In some examples, an etch stop layer 122 may be formed over the metal interconnect structures 118, where the etch stop layer 122 may have a thickness of about 30 nm to 80 nm and may comprise materials such as SiCN, SiC, SiCO, SiON, or Si₃N₄, and the like, similar to the composition of the etch stop layer 112 described previously. A dielectric layer 124 formed over the etch stop layer 122 may include an ILD and/or IMD having a total thickness of about 120 nm to 1.0 μm. Similar to the composition of the IMD 116, the dielectric layer 124 may include one or more sublayers comprising SiO₂, undoped or doped silicate glass, spin-on-glass, fluorosilicate glass or other low-k dielectric constant material. Further, the dielectric layer 124 may be planarized, e.g., with CMP and/or etchback.

FIG. 1I depicts a stage where one or more next level metal interconnect structures and/or associated inter-level vias are formed in or through the etch stop layer 122 and the dielectric layer 124 for facilitating inter-level connectivity. As illustrated, metal interconnect structures 128 may be formed as part of fabrication of a second metal layer, e.g., comprising copper, that may be provided as a second metallization level (e.g., MET2, MT2 or M2, or terms of similar import) of a multilevel interconnect arrangement of the semiconductor device 100. Depending on implementation within the multilevel interconnect arrangement, the metal interconnect structures 128 may be configured as terminals and/or interconnect traces, where an inter-level via 126 may extend from a respective metal structure 128 and electrically contact a corresponding metal interconnect structure 118 provided as part of a lower level horizontal routing layer. As will be set forth further below, in some arrangements where a same level metallization layer or an upper level metallization layer is implemented for accessing a TFR, inter-level vias 126 may be absent. In an example copper interconnect arrangement, a diffusion barrier layer 130 may be formed surrounding the copper interconnect structures 128 and associated vias 126 (where provided) to enhance the ohmic contact and adhesion of the interconnect structures 128, similar to the barrier layer 120 of the metal interconnect structures 118 described above.

Where a TFR is desired to be integrated in a copper interconnect arrangement as part of a BEOL flow, some examples of the present disclosure provide a resistive layer having suitable characteristics formed on top of a metal interconnect layer rather than between two adjacent metal interconnect layers, e.g., within an ILD/IMD, an arrangement referred to herein as inter-level TFR integration. As noted previously, inter-level TFR integration arrangements are beset with various deficiencies, including being limited by the spatial constraints of thin ILDs of advanced interconnect technologies. Accordingly, some examples herein may be configured to position a resistive layer to electrically contact metal interconnect structures formed as part of a metallization layer, where the metal interconnect structures are operable as TFR terminals without requiring separate header ends (or “heads”) for the TFR. To prevent or otherwise mitigate the effects of migration, diffusion and/or corrosion from the copper (Cu) terminals, a suitable TFR terminal diffusion barrier may be formed over the Cu metal interconnect structures. In some examples, terminal diffusion barrier layers having a suitable thickness may be formed using area selective metal deposition, which allows depositing materials in only desired areas of an underlying patterned layer, e.g., the patterned copper interconnect structures, thus avoiding additional photo/mask steps.

FIG. 1J depicts a stage where terminal diffusion barrier layers 132 are formed over the metal interconnect structures 128, which may be configured to operate as TFR terminals in an example. Depending on implementation, the metal interconnect structures 128 may be configured to operate as diffusion-protected terminals extending from a top surface 157 of the ILD/IMD layer 124 toward the semiconductor substrate 102 for providing connectivity with respect to a TFR integrated in a BEOL flow. In some implementations, the terminal diffusion barrier layers 132 may have a thickness of about 2 nm to 10 nm and may comprise Co, W, etc., formed by area selective deposition, such as, electroless plating, and the like, implemented by CVD/ALD tooling. In some additional and/or alternative arrangements, the terminal diffusion barrier layers 132 may comprise metal nitride materials such as TaN, TiN, WN, and/or MON.

FIG. 1K depicts a stage where a resistive layer 134 operable as a TFR is formed over the terminal diffusion barrier layers 132. Similar to the fabrication of the resistive layer 110 in a pre-BEOL integration flow, the resistive layer 134 may be formed by depositing and patterning an optional hardmask layer (e.g., an LDR TEOS hardmask having a thickness of about 20 nm to 60 nm, not shown in FIG. 1K), where a resistive body may comprise materials such as SiCr, NiCr, etc., having suitable resistivity. Likewise, the resistive layer 134 may have dimensions and form factors (e.g., thickness, length and width) similar to that of the pre-BEOL resistive layer 110 in some examples. As illustrated in FIG. 1K, the resistive layer 134 may be formed over the terminal diffusion barrier layers 132, where respective termini 197A, 197B of the resistive layer 134 may completely overlap the corresponding the terminal diffusion barrier layers 132 in an example arrangement. Depending on process flow implementation, the resistive layer 134 may be conformally formed, e.g., the resistive layer 134 conformally overlapping a sidewall of the terminal diffusion barrier layer 132 in some arrangements. Based upon relative (co) planarity of the top surfaces of the terminal barrier layer 132 and the top surface 157 of the ILD/IMD layer 124, the resistive layer 134 may be formed as a resistive body having a suitable surface topography. Regardless of the surface topography of the resistive layer 134, the terminal diffusion barrier layers 132 are configured to facilitate direct electrical contact to the underlying metal interconnect structures 128, thereby obviating the need for separate space-consuming head structures at respective termini 197A, 197B of the resistive layer 134.

In some examples, connectivity to the metal interconnect structures 128 may be established by way of lower level interconnect structures, e.g., by way of vias 126 and interconnect structures 118 that may be routed to appropriate electrical nodes, e.g., bond pads, etc. (not shown in the Figures) associated with the semiconductor device 100. FIG. 1L-1 depicts a stage where the metal interconnect structures 128 are configured as TFR terminals coupled to respective termini 197A, 197B of the resistive layer 134, with the metal interconnect structures 128 having connectivity based on lower level interconnect structures and/or traces. As illustrated in FIG. 1L-1, an etch stop layer 136 is formed over the resistive layer 134 (and an optional hardmask layer if provided; not shown in the Figures). In some examples, the etch stop layer 136 is similar to the etch stop layers 122 or 112. A next level dielectric layer 138 comprising one or more layers/sublayers may be formed over the etch stop layer 136. Depending on implementation, the etch stop layer 136, dielectric layer 138 and/or a combination thereof may be configured as a second dielectric layer disposed over the resistive layer 134 and in direct contact therewith, where the dielectric layer 124 may be configured as a first dielectric layer according to some examples.

Where the metal interconnect structures 128 are provided as part of a topmost metallization level, the dielectric layer 138 may be operable as a protective overcoat (PO). In some examples, the dielectric layer 138 may have a total thickness of several tens or hundreds of nanometers (nm) to several microns (μm) that may include one or more layers or sublayers of insulator materials such as, e.g., SiN, SiO, oxynitride, polyimide, etc., which may be deposited as part of a BEOL process flow.

In examples herein, regardless of whether an etch stop layer, an IMD layer, or a dielectric stack combining both is configured as a second dielectric layer with respect to an appropriate first dielectric layer, it will be seen that the second dielectric layer may be disposed over a resistive layer operable as a TFR and in direct contact with the resistive layer. Further, the second dielectric layer is thicker than the resistive layer regardless of whether a BEOL-based TFR integration or a pre-metallization TFR integration is implemented.

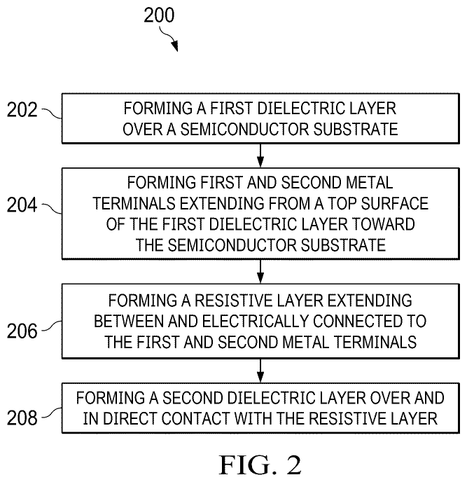

In some examples, connectivity to the metal interconnect structures 128 operable as TFR terminals for the resistive layer 134 may be facilitated by way of upper level interconnects, traces or other routing structures to appropriate electrical nodes (e.g., bond pads, etc.) in the semiconductor device 100 instead of lower level connectivity described above. Where upper level connectivity to the resistive layer 134 is implemented, the termini 197A, 197B of the resistive layer 134 may be patterned to extend over only portions of the terminal diffusion barrier layers 132, thus allowing partially exposed areas of the terminal diffusion barrier layers 132 to be coupled to suitable upper level routing structures. FIG. 1L-2 depicts a stage where the terminal diffusion barrier layers 132 are partially covered by the termini 197A, 197B of the resistive layer 134, thus exposing areas 139 that may be used as landing pads for vias 135 that may be formed in or through a dielectric layer or stack according to some additional and/or alternative arrangements of the present disclosure. To accommodate minimum critical dimension (CD) design rules, the underlying metal interconnect structures 128 may be (re) sized appropriately (e.g., larger than the sizing implemented in the example of FIG. 1L-1). Concomitantly, the terminal diffusion barrier layers 132 may also be (re) sized as shown in FIG. 1L-2. As illustrated, an ILD 140 and an IMD 144 are formed over the etch stop layer 136, where the ILD 140 may have a thickness of about 40 nm to 500 nm and the IMD 144 may have a thickness of about 80 nm to 500 nm. In one arrangement, vias 135 are formed over the exposed areas 139 of the terminal diffusion barrier layers 132 and may extend to metal interconnect structures or traces 137 formed in the IMD 144. A diffusion barrier layer 141 may be formed surrounding the interconnect structures 137 and corresponding vias 135 similar to the diffusion barrier layer 130 described above. In this example, the etch stop layer 136, the ILD layer 140, the IMD layer 144, and/or a combination thereof may be configured as a second dielectric layer disposed over the resistive layer 134 and in direct contact therewith, where the dielectric layer 124 may be configured as a first dielectric layer similar to the examples set forth above. Although not specifically shown in FIG. 1L-2, the semiconductor device 100 may include a PO layer formed over the IMD 144 in subsequent stages.

In further examples, connectivity to the metal interconnect structures 128 operable as TFR terminals for the resistive layer 134 may be facilitated by way of routing on a same level that the metal interconnect structures 128 are provided. FIG. 1L-3 depicts a stage where the metal interconnect structures 128 are extended horizontally for facilitating routing/connectivity to appropriate electrical nodes (e.g., bond pads, etc., not shown in the Figures) with respect to the resistive layer 134 of the semiconductor device 100. In the illustrated example, both metal interconnect structures 128 are shown as being extended along one axis, e.g., along the X-axis, although different routing schemes may be implemented in other examples. In some arrangements, one of the metal interconnect structures 128 may be extended along a first axis (e.g., the X-axis) whereas the other metal interconnect structure 128 may be extended along a second axis (e.g., the Y-axis) orthogonal to the first axis. In some arrangements, both metal interconnect structures 128 may be extended along the Y-axis. Depending on implementation, the termini 197A, 197B of the resistive layer 134 may be patterned to extend over portions of the terminal diffusion barrier layers 132 formed over the metal interconnect structures 128. Similar to the arrangements set forth previously, one or more dielectric layers 160, 162 may be formed over the etch stop layer 136, where the thicknesses of the dielectric layers 160, 162 may vary depending on implementation.

FIG. 2 depicts a flowchart of an IC fabrication method 200 according to some examples. In a representative arrangement, the method 200 may commence with forming a first dielectric layer over a semiconductor substrate as set forth at block 202, which may relate to aspects of fabricating a PMD layer (e.g., the PMD layer 104) or an ILD/IMD layer (e.g., ILD/IMD layer 124) as set forth above. At block 204, first and second metal terminals may be formed, which extend from a top surface of the first dielectric layer toward the semiconductor substrate, which may relate to aspects of fabricating tungsten contacts 108 or copper damascene structures such as the metal interconnects 128 described above. At block 206, a resistive layer may be formed that extends between and is electrically connected to the first and second metal terminals, which may relate to aspects of fabricating the resistive layers 110 or 134 as described above. At block 208, a second dielectric layer having direct contact with the resistive layer is formed over the resistive layer, which may relate to aspects of fabricating any one and/or combination of dielectric layers overlying the resistive layers 110 or 134 as described above.

As noted previously, some examples set forth herein may include only a pre-BEOL resistive layer such as the resistive layer 110 (pre-BEOL pr pre-metallization TFR integration), some examples may include only a metal level resistive layer (e.g., a top level metal) such as the resistive layer 134 (BEOL-based TFR integration), and some examples may include both pre-BEOL and top level resistive layers. Accordingly, various TFR integration schemes of the present disclosure may be implemented separately and/or combined in multiple ways to obtain different configurations of integrated TFRs having appropriate materials, compositions, form factors, etc., depending on the application, level of integration, technology nodes and/or process flows involved.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), PECVD, or atomic layer deposition (ALD), etc. As another example, silicon nitride may be a silicon-rich silicon nitride or an oxygen-rich silicon nitride. Silicon nitride may contain some oxygen, but not so much that the materials dielectric constant is substantially different from that of high purity silicon nitride.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. In addition, terms such as “over”, “under”, “below”, etc., relative to the spatial orientation of two components does not necessarily mean that one component is immediately over the other component, or that one component is immediately under or below the other component. Further, the features and/or components of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. An integrated circuit (IC), comprising:
a first dielectric layer over a semiconductor substrate;
first and second metal terminals extending from a top surface of the first dielectric layer toward the semiconductor substrate;
a resistive layer extending between and electrically connected to the first and second metal terminals; and
a second dielectric layer over and in direct contact with the resistive layer.

2. The IC of claim 1, wherein the second dielectric layer is thicker than the resistive layer.

3. The IC of claim 1, further comprising an interconnect metal structure extending through the second dielectric layer and conductively connecting to the first or second metal terminal.

4. The IC of claim 3, wherein the interconnect metal structure is a via.

5. The IC of claim 1, wherein the resistive layer conformally covers a sidewall of a metal diffusion barrier layer on the first metal terminal.

6. The IC of claim 5, wherein the metal diffusion barrier layer comprises cobalt or tungsten.

7. The IC of claim 1, wherein the first and second metal terminals are in a horizontal metal interconnect routing layer.

8. The IC of claim 1, wherein the first and second metal terminals are tungsten contacts.

9. The IC of claim 1, wherein the first and second metal terminals comprise copper.

10. A method, comprising:
forming a first dielectric layer over a semiconductor substrate;
forming first and second metal terminals extending from a top surface of the first dielectric layer toward the semiconductor substrate;
forming a resistive layer extending between and electrically connected to the first and second metal terminals; and
forming a second dielectric layer over and in direct contact with the resistive layer.

11. The method of claim 10, wherein the resistive layer is conformally formed to cover a sidewall of a metal diffusion barrier layer on the first metal terminal.

12. The method of claim 11, wherein the metal diffusion barrier layer is formed by area selective metal deposition and comprises cobalt or tungsten.

13. The method of claim 10, wherein the first and second metal terminals are formed in a horizontal metal interconnect routing layer.

14. The method of claim 10, wherein the first dielectric layer is a pre-metal dielectric (PMD) layer and the first and second metal terminals are formed as tungsten contacts in the PMD layer and coupled to polysilicon interconnect traces.

15. The method of claim 10, wherein the resistive layer is selected from the group consisting of silicon chromium (SiCr) and nickel chromium (NiCr).

16. An integrated circuit (IC), comprising:
a pre-metal dielectric (PMD) layer over a semiconductor substrate;
first and second polysilicon traces between the PMD layer and the semiconductor substrate;
first and second metal contacts in the PMD layer, each extending vertically from a corresponding polysilicon trace to a top surface of the PMD layer;
a resistive layer over the PMD layer and electrically connected to the first and second metal contacts; and
a second dielectric layer over the resistive layer.

17. The IC of claim 16, further comprising a copper interconnect formed through the second dielectric layer.

18. The IC of claim 16, further comprising an aluminum interconnect formed through the second dielectric layer.

19. The IC of claim 16, wherein the first and second metal contacts are tungsten contacts.

20. The IC of claim 16, wherein the resistive layer is selected from the group consisting of silicon chromium (SiCr) and nickel chromium (NiCr).
